(19) United States
(12) Patent Application Publication
(10) Pub. No.: US 2021/0289661 A1
(43) Pub. Date: Sep. 16, 2021

(54) HEAT DISSIPATION DEVICE

(71) Applicant: Zyxel Networks Corporation, New Taipei City (TW)

(72) Inventors: Lu-Wei Chiang, Hsinchu City (TW); Liang-Wei Chen, Hsinchu City (TW); Hui-Lung Chien, Hsinchu City (TW)

(73) Assignee: Zyxel Networks Corporation, New Taipei City (TW)

(21) Appl. No.: 16/896,232

(22) Filed: Jun. 9, 2020

(30) Foreign Application Priority Data
Mar. 13, 2020 (TW) 109108468

(51) Int. Cl. H05K 7/20; F28F 21/06

(52) U.S. Cl. CPC H05K 7/20218; H05K 7/2039; F28F 21/062

(57) ABSTRACT

A heat dissipation device adapted to dissipate heat of a heat source in an electronic system. The heat dissipation device includes a thermally conductive plastic shell and a fluid. The thermally conductive plastic shell has at least one sealed accommodation space. The fluid completely fills the at least one sealed accommodation space of the thermally conductive plastic shell.

### CROSS-REFERENCE TO RELATED APPLICATION

This application claims the priority benefit of Taiwan application serial no. 109108468, filed on Mar. 13, 2020. The entirety of the above-mentioned patent application is hereby incorporated by reference herein and made a part of this specification.

### BACKGROUND

### Technical Field

The disclosure relates to a heat dissipation device, and more particularly, to a heat dissipation device applied in an electronic system.

### Description of Related Art

As the 5G era approaches, the demand for featuring short, compact, light, and thin product design becomes the main trend in the development of the network communication equipment. Since electronic products are required to provide more functionalities and high transmission speed, the heating power of electronic components and systems rises, and the heat flux of electronic elements increases continuously as well. Regarding the network communication equipment, it becomes the key technique how to effectively solve the heat dissipation problem in a network communication equipment.

At present, a liquid cooled metal heat dissipation device is mainly used as the heat dissipation device applied in the network communication equipment, and the material of such device includes copper, stainless steel, or aluminum. Pure water may be used as the coolant if copper or stainless steel is used as the material of the metal shell. Nevertheless, the costs of copper or stainless steel are high. Moreover, under high temperature for a long time, copper or stainless steel may be oxidized, and thereby reducing reliability. If the low-cost aluminum is adopted to make the metal shell, since pure water may corrode aluminum, only acetone, which pollutes the environment considerably, may be used as the coolant. Besides the problem of higher cost, the shell made of metallic materials may form an antenna which radiate high-speed signals out, as such, an electromagnetic interference problem is generated. The receiver sensitivity of wireless products is often interfered by these unexpected signals, that is “desense”, which means the degradation in receiver sensitivity.

### SUMMARY

The disclosure provides a heat dissipation device adapted to dissipate heat of a heat source in an electronic system and featuring advantages of low costs and easy production without causing an additional problem of electromagnetic interference.

A heat dissipation device provided by the disclosure is adapted to dissipate heat of at least one heat source in an electronic system. The heat dissipation device includes a thermally conductive plastic shell and a fluid. The thermally conductive plastic shell has at least one sealed accommodation space. The fluid completely fills the at least one sealed accommodation space of the thermally conductive plastic shell.

In an embodiment of the disclosure, the sealed accommodation space is a vacuum space.

In an embodiment of the disclosure, the fluid is a liquid substance with a characteristic of chemical heat dissipation or physical heat dissipation.

In an embodiment of the disclosure, the fluid includes water, hydrogel, antifreeze, water mixed with antifreeze, or thermal grease.

In an embodiment of the disclosure, the thermally conductive plastic shell includes a division portion. The at least one sealed accommodation space includes a first sealed accommodation space and a second sealed accommodation space. The division portion is located between the first sealed accommodation space and the second sealed accommodation space.

In an embodiment of the disclosure, the first sealed accommodation space and the second sealed accommodation space are stacked in an up-and-down manner.

In an embodiment of the disclosure, the first sealed accommodation space and the second sealed accommodation space are adjacent to each other in a left-and-right manner.

In an embodiment of the disclosure, the thermally conductive plastic shell includes a plurality of division portions. The at least one sealed accommodation space includes a first sealed accommodation space, a second sealed accommodation space, a third sealed accommodation space, and a fourth sealed accommodation space. The division portions are located among the first sealed accommodation space, the second sealed accommodation space, the third sealed accommodation space, and the fourth sealed accommodation space.

In an embodiment of the disclosure, the first sealed accommodation space and the second sealed accommodation space are adjacent to each other in a left-and-right manner. The third sealed accommodation space and the fourth sealed accommodation space are adjacent to each other in a left-and-right manner. The first sealed accommodation space and the third sealed accommodation space are stacked in an up-and-down manner. The second sealed accommodation space and the fourth sealed accommodation space are stacked in an up-and-down manner.

In an embodiment of the disclosure, the at least one sealed accommodation space includes a first space, a second space, and a connection space adjacent to and communicating with one another. The first space is parallel to the second space, and the connection space vertically connects the first space and the second space.

In an embodiment of the disclosure, in a cross-sectional view, the first space, the connection space, and the second space are arranged in an I shape.

In an embodiment of the disclosure, in a cross-sectional view, the first space, the connection space, and the second space are arranged in a U shape.

In an embodiment of the disclosure, the thermally conductive plastic shell includes a first portion and a second portion assembled together. The sealed accommodation space is located between the first portion and the second portion.

In an embodiment of the disclosure, the first portion and the second portion are assembled together in an up-and-down combination manner or a left-and-right combination manner.

In an embodiment of the disclosure, the heat dissipation device includes a plurality of fixing parts penetrating through the first portion and the second portion to assemble the first portion and the second portion together.

In an embodiment of the disclosure, each of the fixing parts includes a screw or a bolt.

To sum up, in the heat dissipation device provided by the disclosure, the fluid completely fills the sealed accommodation space of the thermally conductive plastic shell, so that the surface temperature of the thermally conductive plastic shell is uniform. That is, temperature uniformity is achieved. The heat energy generated by the heat source in the electronic system may be transferred to the fluid in the sealed accommodation space through the thermally conductive plastic shell. The heat dissipation effect is thereby improved through the principles of specific heat capacity or the increased heat dissipation area. In the heat dissipation device provided by the disclosure, the electromagnetic interference problem generated by a metal shell used in the prior art when dissipating heat from a heat source in the electronic system may be prevented, since the thermally conductive plastic shell is adopted. In addition, the thermally conductive plastic shell provided by the disclosure not only features low costs, easy production, and thereby enhanced competitiveness, but also allows the heat dissipation device to have a reduced overall weight, so that the requirement for a lightweight product design is satisfied.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A is a schematic three-dimensional view of a heat dissipation device according to an embodiment of the disclosure.

FIG. 1B is a schematic cross-sectional view of the heat dissipation device of FIG. 1A.

FIG. 2A is a schematic three-dimensional view of a heat dissipation device according to another embodiment of the disclosure.

FIG. 2B is a schematic cross-sectional view of the heat dissipation device of FIG. 2A.

FIG. 3A is a schematic three-dimensional view of a heat dissipation device according to another embodiment of the disclosure.

FIG. 3B is a schematic cross-sectional view of the heat dissipation device of FIG. 3A.

FIG. 4A is a schematic three-dimensional view of a heat dissipation device according to another embodiment of the disclosure.

FIG. 4B is a schematic cross-sectional view of the heat dissipation device of FIG. 4A.

FIG. 5A is a schematic three-dimensional view of a heat dissipation device according to another embodiment of the disclosure.

FIG. 5B is a schematic cross-sectional view of the heat dissipation device of FIG. 5A.

FIG. 6A is a schematic three-dimensional view of a heat dissipation device according to another embodiment of the disclosure.

FIG. 6B is a schematic cross-sectional view of the heat dissipation device of FIG. 6A.

FIG. 7 is a schematic three-dimensional exploded view of a thermally conductive plastic shell according to another embodiment of the disclosure.

FIG. 8 is a schematic three-dimensional exploded view of a thermally conductive plastic shell according to another embodiment of the disclosure.

FIG. 9 is a schematic three-dimensional exploded view of a portion of a heat dissipation device according to another embodiment of the disclosure.

### DESCRIPTION OF THE EMBODIMENTS

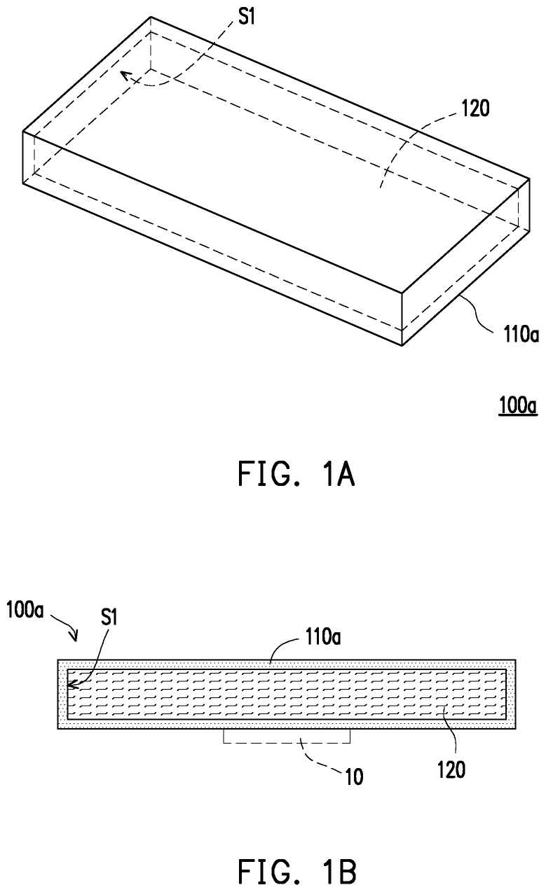

FIG. 1A is a schematic three-dimensional view of a heat dissipation device according to an embodiment of the disclosure. FIG. 1B is a schematic cross-sectional view of the heat dissipation device of FIG. 1A. With reference to FIG. 1A and FIG. 1B together, in this embodiment, a heat dissipation device 100a is adapted to dissipate heat of at least one a heat source 10 in an electronic system. Herein, the electronic system is, for example, a network communication system, and the electrical specifications of this network communication system mainly include a high-speed transmission interface, a multi-port network switch (Ethernet switch), an optical fiber communication product, or a wireless communication product (e.g., 3G, 4G, 5G, or Wi-Fi), but are not limited thereto. The heat source 10 is, for example, a central processing unit, a 3G/4G/5G transceiver, a WiFi transceiver, a GPON/EPON transceiver, or a System-On-Chip (SOC), but is not limited thereto.

To be specific, the heat dissipation device 100a of this embodiment includes a thermally conductive plastic shell 110a and a fluid 120. The thermally conductive plastic shell 110a has at least one sealed accommodation space (one sealed accommodation space S1 is schematically depicted), and a thermal conductivity coefficient of the thermally conductive plastic shell 110a is, preferably, equal to or greater than 1 W/mK. Specifically, the fluid 120 completely fills the sealed accommodation space S1 of the thermally conductive plastic shell 110a. Herein, the fluid 120 is a liquid substance with a characteristic of chemical heat dissipation or physical heat dissipation and may be, for example, water, hydrogel, antifreeze, water mixed with antifreeze, or thermal grease, but is not limited thereto. A composition of the antifreeze is, for example, methanol, ethanol, ethylene glycol, or propylene glycol, but is not limited thereto. In short, the heat dissipation device 100a of this embodiment is implemented as a liquid cooled heat dissipation device.

Furthermore, in this embodiment, the thermally conductive plastic shell 110a is, for example, an integrally-formed rectangular thermally conductive plastic shell, and the sealed accommodation space S1 is, for example, a rectangular sealed accommodation space, but is not limited thereto. In particular, the sealed accommodation space S1 of this embodiment is implemented as a vacuum space. The surface temperature of the thermally conductive plastic shell 110a is uniform since the fluid 120 completely fills the sealed accommodation space S1 of the thermally conductive plastic shell 110a, that is, temperature uniformity is achieved. Compared to the fluid 120 with low thermal resistance, air is a heat medium having high thermal resistance. If there's an air layer in the sealed accommodation space S1 besides the fluid 120, temperature uniformity may not be achieved. As such, a poor heat dissipation effect may thus be provided by the heat dissipation device 100a. Moreover, a specific heat capacity of the fluid 120 adopted by this embodiment (e.g., water, having a specific heat capacity of 1.000 cal/g° C.) is greater than that of the conventionally-adopted acetone (having a specific heat capacity of 0.519 cal/g° C.). That is, in this embodiment, a coolant, which has higher specific heat capacity and is a non-metallic liquid, is adopted and thus demonstrates greater tolerance and heat resistance to heat capacity. In this way, the heat dissipation device 100a of this embodiment may provide improved heat dissipation effect. In addition, compared to copper, aluminum, and acetone used in the prior art, the thermally conductive plastic shell 110a and the fluid 120 adopted by this embodiment produce less pollutants and carbon emissions. The heat dissipation device 100a of this embodiment thereby exhibits environmental protection and economic value features.

Further, a high-speed interface of a product in the electronic system (e.g., a network communication system) may bring electromagnetic interference, the shell of the heat dissipation device 100a of this embodiment is made of thermally conductive plastic featuring non-hazardous electrical characteristics. The heat energy generated by the heat source 10 in the electronic system may be transferred to the fluid 120 in the sealed accommodation space S1 through the thermally conductive plastic shell 110a. The heat dissipation effect is thereby improved through the principles of specific heat capacity or the increased heat dissipation area, so that the electromagnetic interference problem may be prevented from occurring and reliability and quality of an electronic product may thus be effectively improved. Compared to a metal shell used in the prior art, the thermally conductive plastic shell 110a of this embodiment not only features low costs, easy production, and thereby enhanced competitiveness, but also allows the heat dissipation device 100a to have a reduced overall weight, so that the requirement for lightweight product design is satisfied.

Note that if the thermal conductivity coefficient of the thermally conductive plastic shell 110a is equal to or greater than 4 W/mK, due to the material properties, the thermally conductive plastic shell 110a may act as a favorable electromagnetic material to absorb electromagnetic waves. In addition, in other embodiments that are not shown, the thermally conductive plastic shell may also include a liquid inlet. The fluid may be injected into the sealed accommodation space through the liquid inlet, and then the liquid inlet is sealed after the sealed accommodation space is filled with the fluid. In other embodiments, a physical liquid inlet may not be present on an appearance through a manufacturing technique.

It should be noted that the reference numerals and a part of the contents in the previous embodiment are used in the following embodiments, in which identical reference numerals indicate identical or similar components, and repeated description of the same technical contents is omitted. Please refer to the descriptions of the previous embodiment for the omitted contents, which will not be repeated hereinafter.

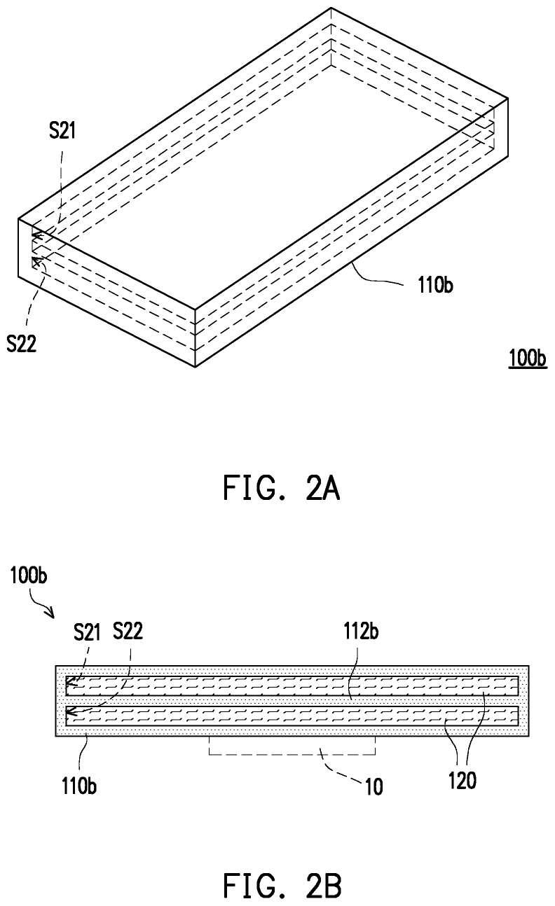

FIG. 2A is a schematic three-dimensional view of a heat dissipation device according to another embodiment of the disclosure. FIG. 2B is a schematic cross-sectional view of the heat dissipation device of FIG. 2A. Referring to FIG. 1A, FIG. 1B, FIG. 2A, and FIG. 2B together, a heat dissipation device 100b of this embodiment is similar to the foregoing heat dissipation device 100a, and a difference therebetween lies in that: a thermally conductive plastic shell 110b of this embodiment includes a division portion 112b. The at least one sealed accommodation space includes a first sealed accommodation space S21 and a second sealed accommodation space S22. The division portion 112b is located between the first sealed accommodation space S21 and the second sealed accommodation space S22. Herein, the first sealed accommodation space Si and the second sealed accommodation space S22 are stacked in an up-and-down manner, that is, multiple cavities are arranged in a longitudinal direction.

In this embodiment, arrangement of the division portion 112b is to “intercept” heat energy, that is, thermal interception. In this way, a speed of transferring heat to the first sealed accommodation space S21 is reduced, and thereby enhancing the efficiency of heat dissipation of the first sealed accommodation space S21. When heat is transferred from the heat source 10 in the electronic system to the heat dissipation device 100b, the fluid 120 in the second sealed accommodation space S22 is heated to a temperature that is close to the temperature of the heat source 10 first. At this moment, the heat is also transferred to the first sealed accommodation space S21 by the division portion 112b. Since the speed of heat transmission is lowered owing to the division portion 112b, the temperature of the first sealed accommodation space S21 may not rise excessively, so that heat may be efficiently dissipated into the air through an upper surface of the thermally conductive plastic shell 110b and through air convection. In short, through the design of the thermally conductive plastic shell 110b provided by the present embodiment, the instant thermal saturation is prevented from taking place, which may affect the heat dissipation rate of the heat source 10. In other words, a thermal interception effect is more obvious as the number of the division portions in the sealed accommodation space increases, and the efficiency of heat dissipation provided by the heat dissipation device 100b may also be improved.

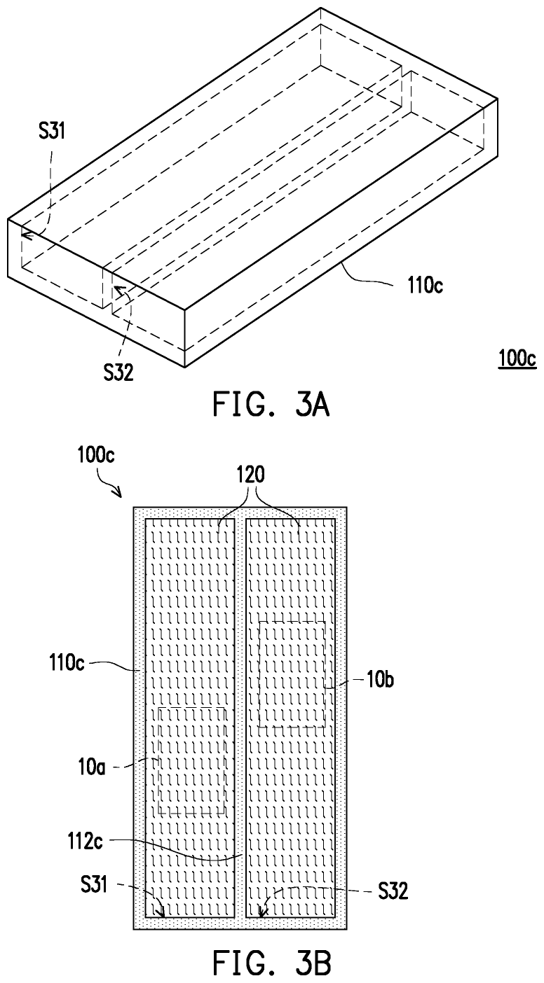

FIG. 3A is a schematic three-dimensional view of a heat dissipation device according to another embodiment of the disclosure. FIG. 3B is a schematic cross-sectional view of the heat dissipation device of FIG. 3A. Referring to FIG. 1A, FIG. 1B, FIG. 3A, and FIG. 3B together, a heat dissipation device 100c of this embodiment is similar to the foregoing heat dissipation device 100a, and a difference therebetween lies in that: a thermally conductive plastic shell 110c of this embodiment includes a division portion 112c. The at least one sealed accommodation space includes a first sealed accommodation space S31 and a second sealed accommodation space S32. The division portion 112c is located between the first sealed accommodation space S31 and the second sealed accommodation space S32. Herein, the first sealed accommodation space S31 and the second sealed accommodation space S32 are adjacent to each other in a left-and-right manner, that is, multiple cavities are arranged in a horizontal direction.

In this embodiment, arrangement of the division portion 112c is to “fence” heat energy, that is, thermal fencing. In this way, a heat of a heat source 10a in the electronic system is prevented from being rapidly transferred to the second sealed accommodation space S32 through the first sealed accommodation space S31, which may cause a heat source 10b in the electronic system to be heated instead. Furthermore, if a temperature of the heat source 10a is greater than a temperature of the heat source 10b and there's no division portion 112c provided for heat blocking, the heat may be rapidly transferred to a heat dissipation region of the heat source 10b with a lower temperature when the temperature of the heat source 10a is close to the temperature of the fluid 120 in the first sealed accommodation space S31. As such, the heat source 10b having the lower temperature may be heated, and an electronic component may thus be damaged. In this embodiment, heat is fenced in a horizontal direction via the design of the division portion 112c. In this way, the heat of the fluid 120 in the first sealed accommodation space S31 is prevented from being rapidly transferred to the fluid 120 in the second sealed accommodation space S32. In this way, the fluid 120 in the second sealed accommodation space S32 may have sufficient heat capacity to remove the heat of the heat source 10b, so that heat may be efficiently dissipated into air through a surface of the thermally conductive plastic shell 110c and through air convection.

In short, in the design of the thermally conductive plastic shell 110c provided by the present embodiment, multiple cavities are arranged in a horizontal direction through “blocking” of the division portion 112c, and the multiple cavities are used to “fence” heat in respective regions of the cavities so that the heat may be dissipated in the respective regions of the cavities. The chamber (i.e., the internal space of the thermally conductive plastic shell) is not entirely heated, and the heat is prevented from transferring to the other regions to affect the efficiency of heat dissipation of the region with the low temperature. In other words, a thermal fencing effect is more obvious as the number of division portions increases, and the performance of the heat dissipation device 100c may also be improved.

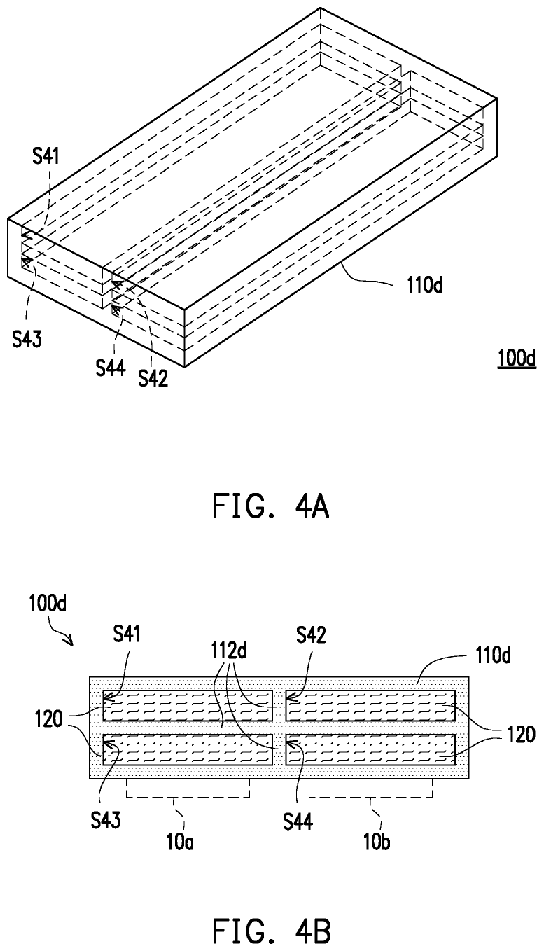

FIG. 4A is a schematic three-dimensional view of a heat dissipation device according to another embodiment of the disclosure. FIG. 4B is a schematic cross-sectional view of the heat dissipation device of FIG. 4A. Referring to FIG. 2A, FIG. 2B, FIG. 3A, FIG. 3B, FIG. 4A, and FIG. 4B together, a heat dissipation device 100d of this embodiment is similar to the foregoing heat dissipation devices 100b and 100c, and a difference therebetween lies in that: a thermally conductive plastic shell 110d of this embodiment includes a plurality of division portions 112d. The at least one sealed accommodation space includes a first sealed accommodation space S41, a second sealed accommodation space S42, a third sealed accommodation space S43, and a fourth sealed accommodation space S44. The division portions 112d are located among the first sealed accommodation space S41, the second sealed accommodation space S42, the third sealed accommodation space S43, and the fourth sealed accommodation space S44. The first sealed accommodation space S41 and the second sealed accommodation space S42 are adjacent to each other in a left-and-right manner, and the third sealed accommodation space S43 and the fourth sealed accommodation space S44 are adjacent to each other in a left-and-right manner. The first sealed accommodation space S41 and the third sealed accommodation space S43 are stacked in an up-and-down manner, and the second sealed accommodation space S42 and the fourth sealed accommodation space S44 are stacked in an up-and-down manner, that is, multiple cavities are arranged in a horizontal direction and a longitudinal direction simultaneously.

In this embodiment, arrangement of the division portions 112d may “intercept” and “fence” the heat energy, so that the speed of heat transmission to the adjacent cavities in the horizontal direction and the adjacent cavities in the longitudinal direction are lowered. The cavities having a lower temperature are thus prevented from being heated, and the efficiency of heat dissipation of the heat dissipation device 100d is thereby enhanced. Specifically, the division portions 112d divide the thermally conductive plastic shell 110d into the multiple cavities arranged in the longitudinal direction and the multiple cavities arranged in the horizontal direction (i.e., adjacent to each other). The multiple cavities arranged in the horizontal direction may “fence” the heat in the respective regions of the cavities wherein the heat is dissipated, so the chamber (i.e., the internal space of the thermally conductive plastic shell) is not entirely heated and the heat won't be transferred to other regions. The multiple cavities arranged in the longitudinal direction may “intercept” the heat, so that the surface temperature of the heat dissipation device 100d may be lower. The thermal fencing and thermal interception effects are more obvious as the number of division portions increases, and the performance of the heat dissipation device 100d may also be improved.

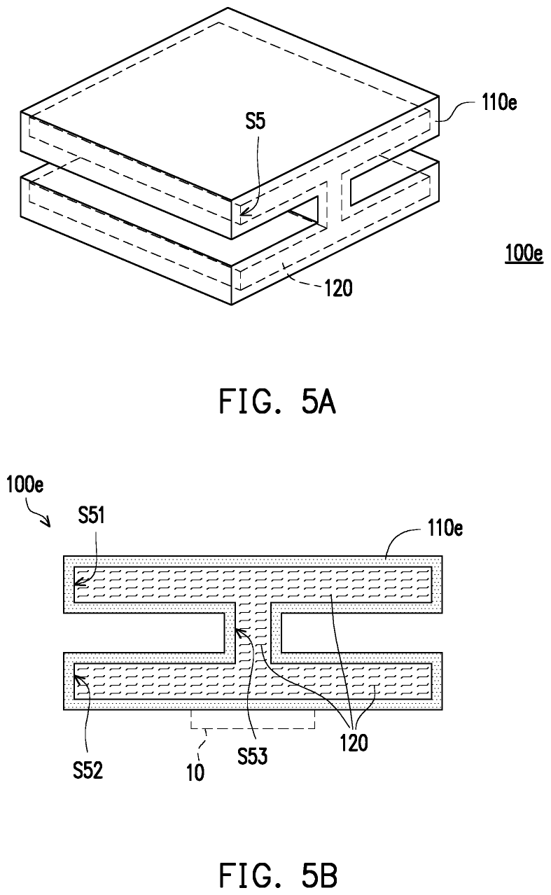

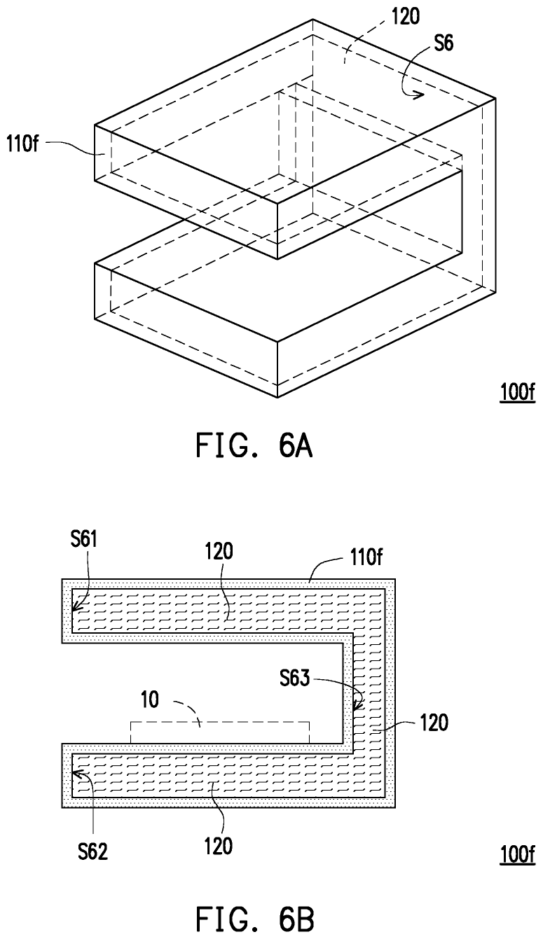

FIG. 5A is a schematic three-dimensional view of a heat dissipation device according to another embodiment of the disclosure. FIG. 5B is a schematic cross-sectional view of the heat dissipation device of FIG. 5A. Referring to FIG. 1A, FIG. 1B, FIG. 5A, and FIG. 5B together, a heat dissipation device 100e of this embodiment is similar to the foregoing heat dissipation device 100a, and a difference therebetween lies in that: a sealed accommodation space S5 of a thermally conductive plastic shell 110e of this embodiment includes a first space S51, a second space S52, and a connection space S53 adjacent to and communicating with one another. The first space S51 is parallel to the second space S52, and the connection space S53 vertically connects the first space S51 and the second space S52. In a cross-sectional view, the first space S51, the connection space S53, and the second space S52 are arranged in an I shape, and an outer contour of the thermally conductive plastic shell 110e is I-shaped as well. That is, an outer surface of the connection space S53 of the thermally conductive plastic shell 110e is surrounded by air.

In the design of the sealed accommodation space S5, the heat energy generated by the heat source 10 is brought to the connection space S53 and the first space S51 located above, so that twice or greater heat dissipation volume is provided. The narrow connection space S53 is used for a slow thermocycling, so that an effect of “cooling in cavities” is provided. Herein, the outer surface of the connection space S53 is surrounded by air, so that a heat dissipation area is increased, and the first space S51 is also isolated from the second space S52. Specifically, after the fluid 120 in the second space S52 is heated to a certain temperature, the high-temperature fluid 120 may counterflow and mix with the low-temperature fluid 120 in the first space S51 through the connection space S53. At this moment, the first space S51 provides greater heat capacity, and the narrow connection space S53 slows down the flowing speed as well. In this way, the high-temperature fluid 120 in the second space S52 may slowly flow into the first space S51 in a small amount and mix with a large amount of the fluid 120 (which is at a lower temperature) in the first space S51, so that the cooling efficiency is enhanced. As the number of longitudinal layers (i.e., S51 and S52) and air division layers (i.e., the connection space S53 and/or the air surrounding S53) increases, a “cooling in cavities” effect is more obvious, and the efficiency of heat dissipation provided by the heat dissipation device 100e may also be improved.

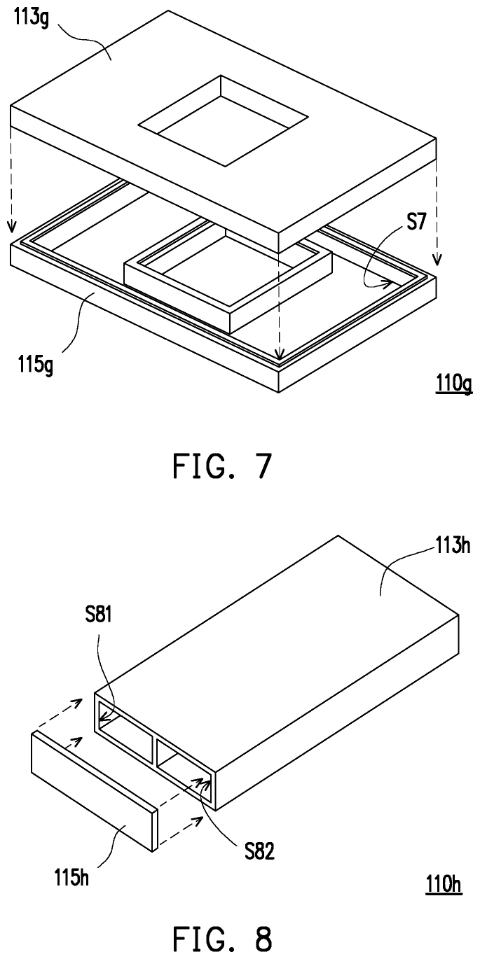

FIG. 6A is a schematic three-dimensional view of a heat dissipation device according to another embodiment of the disclosure. FIG. 6B is a schematic cross-sectional view of the heat dissipation device of FIG. 6A. Referring to FIG. 5A, FIG. 5B, FIG. 6A, and FIG. 6B together, a heat dissipation device 100f of this embodiment is similar to the foregoing heat dissipation device 100e, and a difference therebetween lies in that: in a cross-sectional view, a first space S61, a connection space S63, and a second space S62 are arranged in a left-inverted U shape, and an outer contour of a thermally conductive plastic shell 110f is left-inverted-U-shaped as well.

In the design of a sealed accommodation space S6, the heat energy generated by the heat source 10 is brought to the connection space S63, which is located on a side, and the first space S61 located above, so that twice or greater heat dissipation volume is provided. The high-temperature fluid 120 in the second space S62 is allowed to circulate and flow to the first space S61 through the connection space S63. One side of the connection space S63 is surrounded by air, so that a heat dissipation area is increased, and the first space S61 is also isolated from the second space S62. After the fluid 120 in the second space S62 is heated to a certain temperature, the high-temperature fluid 120 may slowly counterflow and mix with the low-temperature fluid 120 in the first space S61 via the connection space S63. The first space S61 provides greater heat capacity, and the narrow connection space S63 slows down the flowing speed as well. In this way, the high-temperature fluid 120 in the second space S62 may slowly enter the first space S61 in a small amount and mix with a large amount of the fluid 120 (which is at a lower temperature) in the first space S61, so that the cooling efficiency is enhanced. At this moment, if the heat dissipation device 100f is close to a side of a shell (not shown) of the electronic system, heat may be taken away through natural air convection via a through hole (not shown) on the shell. Alternatively, a surface of the thermally conductive plastic shell 110f of the heat dissipation device 100f may be cooled down through the cooler air provided via the through hole of the shell. A “cooling in cavities” effect is more obvious as the number of longitudinal layers (i.e., S61 and S62) and air division layers (i.e., the connection space S63 and/or the air surrounding S63) increases, or as a size of the connection space S63 (which connects the first space S61 and the second space S62) increases, and the efficiency of heat dissipation provided by the heat dissipation device 100f may also be improved.

FIG. 7 is a schematic three-dimensional exploded view of a thermally conductive plastic shell according to another embodiment of the disclosure. Referring to FIG. 1A and FIG. 7 together, a thermally conductive plastic shell 110g of this embodiment is similar to the thermally conductive plastic shell 110a of FIG. 1A, and a difference therebetween lies in that: the thermally conductive plastic shell 110g of this embodiment includes a first portion 113g and a second portion 115g assembled together. A sealed accommodation space S7 is located between the first portion 113g and the second portion 115g. Herein, the thermally conductive plastic shell 110g is a rectangular thermally conductive plastic shell, the first portion 113g and the second portion 115g are assembled together in an up-and-down combination manner, and the sealed accommodation space S7 is an annular sealed accommodation space, so that an increased air contact area is provided. Nevertheless, the disclosure is not limited thereto.

FIG. 8 is a schematic three-dimensional exploded view of a thermally conductive plastic shell according to another embodiment of the disclosure. Referring to FIG. 7 and FIG. 8 together, a thermally conductive plastic shell 110h of this embodiment is similar to the thermally conductive plastic shell 110g of FIG. 7, and a difference therebetween lies in that: in this embodiment, a first portion 113h and a second portion 115h are assembled together in a left-and-right combination manner, sealed accommodation spaces include a first sealed accommodation space S81 and a second sealed accommodation space S82 independent from each other, and each of the first sealed accommodation space S81 and the second sealed accommodation space S82 is a rectangular sealed accommodation space. Nevertheless, the disclosure is not limited thereto.

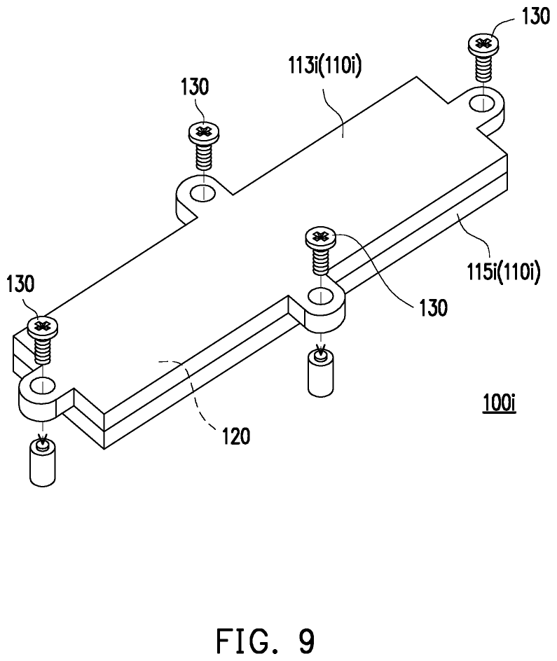

FIG. 9 is a schematic three-dimensional exploded view of a portion of a heat dissipation device according to another embodiment of the disclosure. Referring to FIG. 1A and FIG. 9 together, a heat dissipation device 100i of this embodiment is similar to the heat dissipation device 100a of FIG. 1A, and a difference therebetween lies in that: a thermally conductive plastic shell 110i of this embodiment includes a first portion 113i and a second portion 115i, wherein the first portion 113i and the second portion 115i are assembled together. Further, the heat dissipation device 100i of this embodiment also includes a plurality of fixing parts 130, and the fixing parts 130 penetrate through the first portion 113i and the second portion 115i to assemble the first portion 113i and the second portion 115i together. Herein, each of the fixing parts 130 is, for example, a screw or a bolt.

In view of the foregoing, in the heat dissipation device provided by the disclosure, the fluid completely fills the sealed accommodation space of the thermally conductive plastic shell. In this way, the surface temperature of the thermally conductive plastic shell is uniform, that is, temperature uniformity is achieved. The heat energy generated by the heat source in the electronic system may be transferred to the fluid in the sealed accommodation space through the thermally conductive plastic shell. The heat dissipation effect is thereby improved through the principles of specific heat capacity or the increased heat dissipation area. In the heat dissipation device provided by the disclosure, the electromagnetic interference problem generated by a metal shell used in the prior art when dissipating heat from the heat source in the electronic system may be prevented, since the thermally conductive plastic shell is adopted. In addition, the thermally conductive plastic shell provided by the disclosure not only features low costs, easy production, and thereby enhanced competitiveness, but also allows the heat dissipation device to have a reduced overall weight, so that the requirement for a lightweight product design is satisfied.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A heat dissipation device, adapted to dissipate heat of at least one heat source in an electronic system, the heat dissipation device comprising:
a thermally conductive plastic shell, having at least one sealed accommodation space; and
a fluid, completely filling the at least one sealed accommodation space of the thermally conductive plastic shell.

2. The heat dissipation device according to claim 1, wherein the sealed accommodation space is a vacuum space.

3. The heat dissipation device according to claim 1, wherein the fluid is a liquid substance with a characteristic of chemical heat dissipation or physical heat dissipation.

4. The heat dissipation device according to claim 3, wherein the fluid comprises water, hydrogel, antifreeze, water mixed with antifreeze, or thermal grease.

5. The heat dissipation device according to claim 1, wherein the thermally conductive plastic shell comprises a division portion, the at least one sealed accommodation space comprises a first sealed accommodation space and a second sealed accommodation space, and the division portion is located between the first sealed accommodation space and the second sealed accommodation space.

6. The heat dissipation device according to claim 5, wherein the first sealed accommodation space and the second sealed accommodation space are stacked in an up-and-down manner.

7. The heat dissipation device according to claim 5, wherein the first sealed accommodation space and the second sealed accommodation space are adjacent to each other in a left-and-right manner.

8. The heat dissipation device according to claim 1, wherein the thermally conductive plastic shell comprises a plurality of division portions, the at least one sealed accommodation space comprises a first sealed accommodation space, a second sealed accommodation space, a third sealed accommodation space, and a fourth sealed accommodation space, and the division portions are located among the first sealed accommodation space, the second sealed accommodation space, the third sealed accommodation space, and the fourth sealed accommodation space.

9. The heat dissipation device according to claim 8, wherein the first sealed accommodation space and the second sealed accommodation space are adjacent to each other in a left-and-right manner, the third sealed accommodation space and the fourth sealed accommodation space are adjacent to each other in a left-and-right manner, the first sealed accommodation space and the third sealed accommodation space are stacked in an up-and-down manner, and the second sealed accommodation space and the fourth sealed accommodation space are stacked in an up-and-down manner.

10. The heat dissipation device according to claim 1, wherein the at least one sealed accommodation space comprises a first space, a second space, and a connection space adjacent to and communicating with one another, the first space is parallel to the second space, and the connection space vertically connects the first space and the second space.

11. The heat dissipation device according to claim 10, wherein in a cross-sectional view, the first space, the connection space, and the second space are arranged in an I shape.

12. The heat dissipation device according to claim 10, wherein in a cross-sectional view, the first space, the connection space, and the second space are arranged in a U shape.

13. The heat dissipation device according to claim 1, wherein the thermally conductive plastic shell comprises a first portion and a second portion assembled together, and the at least one sealed accommodation space is located between the first portion and the second portion.

14. The heat dissipation device according to claim 13, wherein the first portion and the second portion are assembled together in an up-and-down combination manner or a left-and-right combination manner.

15. The heat dissipation device according to claim 13, further comprising:
a plurality of fixing parts, penetrating through the first portion and the second portion to assemble the first portion and the second portion together.

16. The heat dissipation device according to claim 15, wherein each of the fixing parts comprises a screw or a bolt.
